(19) United States
(12) Patent Application Publication
(10) Pub. No.: US 2023/0207390 A1
(43) Pub. Date: Jun. 29, 2023

(54) METHOD OF CONTROLLED PROPAGATION OF LASER INDUCED SILICON CRACKS THROUGH A BALANCED COMPRESSIVE AND RETRACTIVE CYCLICAL FORCE FOR LASER DICING

(71) Applicant: TEXAS INSTRUMENTS INCORPORATED, Dallas, TX (US)

(72) Inventors: Jesus Bajo Bautista, JR., Baguio City (PH); Jeniffer Otero Aspuria, Baguio City (PH); Francis Masiglat de Vera, Baguio City (PH)

(21) Appl. No.: 17/561,445

(22) Filed: Dec. 23, 2021

(51) Int. Cl. H01L 21/78; H01L 21/683; H01L 21/268; H01L 21/304; H01L 21/67; B23K 26/53; B23K 26/0622; B28D 5/00

(52) U.S. Cl. CPC H01L 21/78; H01L 21/6836; H01L 21/268; H01L 21/304; H01L 21/67092; B23K 26/53; B23K 26/0622; B28D 5/0011; H01L 2221/68336; B23K 2103/56

(57) ABSTRACT

A method includes applying laser pulses along a direction to a side of a wafer to create first and second stealth damage regions at respective first and second depths in the wafer and to create cracks that extend in the wafer from the respective stealth damage regions and that are spaced apart from one another along the direction, applying a compressive and retractive cyclical force to the wafer along the third direction to propagate and join the cracks from the respective stealth damage regions together, and expanding the wafer to separate individual dies from the wafer.

### BACKGROUND

Die singulation or dicing involves separating individual semiconductor dies from a wafer. Laser cutting can be used to cut the wafer, but higher power settings can lead to uncontrolled crack propagation during laser dicing and splashed laser or splash damage that can damage the active circuitry of the die. Reducing the laser power and or frequency can mitigate laser splash damage, but this can lead to die un-separation and chipping or meander faults where the cutting line breaches the device scribe seal, resulting in reduced product yield.

### SUMMARY

In one aspect, a method of separating dies from a wafer includes applying laser pulses along a direction to a side of a wafer to create first and second stealth damage regions at respective first and second depths in the wafer and to create cracks that extend in the wafer from the respective stealth damage regions and that are spaced apart from one another along the direction, applying a compressive and retractive cyclical force to the wafer along the third direction to propagate and join the cracks from the respective stealth damage regions together, and expanding the wafer to separate individual dies from the wafer.

In another aspect, a method of fabricating an electronic device includes applying laser pulses along a direction to a side of a wafer to create first and second stealth damage regions at respective first and second depths in the wafer and to create cracks that extend in the wafer from the respective stealth damage regions and that are spaced apart from one another along the direction, applying a compressive and retractive cyclical force to the wafer along the third direction to propagate and join the cracks from the respective stealth damage regions together, expanding the wafer to separate individual dies from the wafer, attaching one of the individual dies to a die attach pad or package substrate, electrically connecting a terminal of the one of the individual dies to a circuit or conductive lead, and enclosing the one of the individual dies in a package structure.

In a further aspect, a system includes a laser saw tool, a vibration tool, and a wafer expander tool. The laser saw tool applies laser pulses to a side in a plane of orthogonal first and second directions of a wafer to create first and second stealth damage regions at respective first and second depths in the wafer and to create cracks that extend in the wafer from the respective stealth damage regions and that are spaced apart from one another along a third direction that is orthogonal to the first and second directions. The vibration tool applies a compressive and retractive cyclical force to the wafer along the third direction to propagate and join the cracks from the respective stealth damage regions together, and the wafer expander tool expands the wafer along the first and second directions to separate individual dies from the wafer.

### BRIEF DESCRIPTION OF THE DRAWINGS

FIG. 1 is a system diagram of a die separation system for separating individual semiconductor dies from a wafer. FIG. 1A shows a partial sectional side view of the wafer prior to die separation operations.

FIG. 2 is a flow diagram of a combined method for separating dies from a wafer and fabricating an electronic device.

FIGS. 3 and 3A are a partial sectional side and end elevation views of a portion of a wafer undergoing a first pass of a multi-pass laser stealth cutting operation to create first stealth damage regions at a first depth and associated cracks along a separation path.

FIG. 4 is a partial sectional side elevation view of the wafer undergoing a second pass of the multi-pass laser stealth cutting operation to create second stealth damage regions and associated cracks at a second depth.

FIG. 5 is a partial sectional side elevation view of the wafer undergoing a compressive and retractive cyclical force process to propagate and join the cracks from the respective stealth damage regions together.

FIG. 6 is a top perspective view of the wafer installed on a carrier tape in a wafer expander tool.

FIG. 7 is a top perspective view of the carrier tape expanded to separate individual dies from the wafer.

FIG. 8 is a top perspective view of a packaged electronic device.

### DETAILED DESCRIPTION

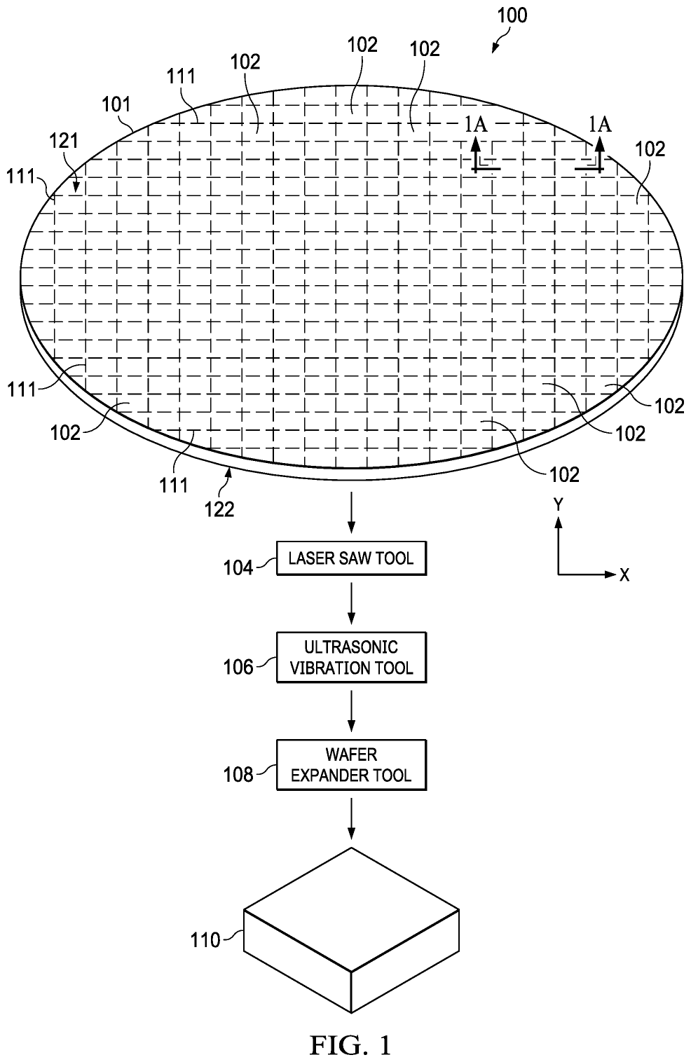

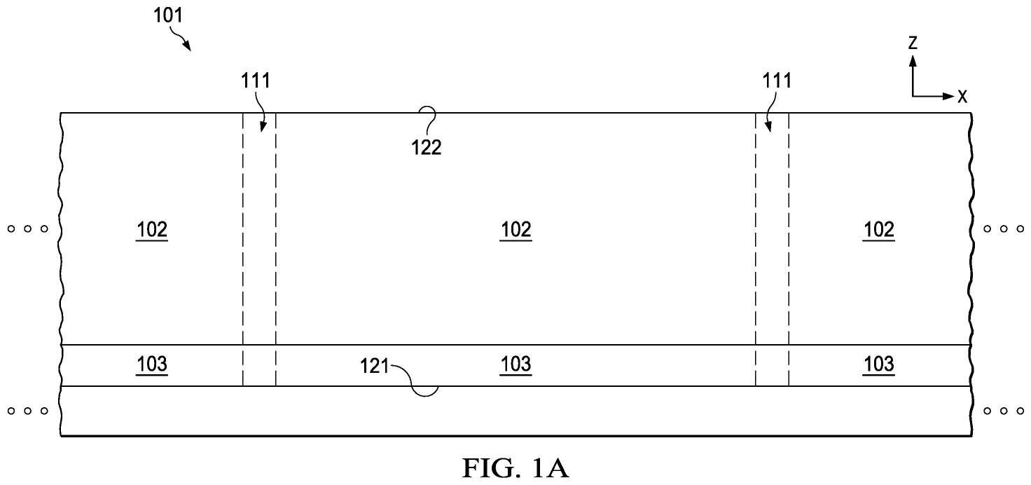

In the drawings, like reference numerals refer to like elements throughout, and the various features are not necessarily drawn to scale. FIG. 1 shows a laser-based die singulation or die separation system 100 for separating individual semiconductor dies from a processed wafer 101. FIG. 1A shows a partial sectional side view of the wafer 101 prior to die separation operations in the system 100. As seen in FIG. 1A, the wafer 101 includes a starting semiconductor layer 102 and an active circuit portion 103 including fabricated components, such as one or more transistors, capacitors, resistors, diodes, etc. (not shown). The system 100 in FIG. 1 includes a laser saw tool 104, an ultrasonic vibration tool 106 and a wafer expander tool 108 and the tools are operated to separate semiconductor dies 110 from the starting wafer 101.

The wafer 101 includes multiple prospective die areas arranged in rows and columns and separated by scribe regions 111 (e.g., prospective separation regions) in which no circuitry is formed. The wafer 101 has generally planar opposite first and second (e.g., top and bottom) sides 121 and 122, and the active circuit portion 103 extends along the first side 121. The sides 121 and 122 of the wafer 101 are shown positioned in respective planes of a first direction X (FIGS. 1 and 1A) and an orthogonal second direction Y (FIG. 1). The first and second sides 121 and 122 are spaced apart from one another along a third direction Z that is orthogonal to the first and second directions X and Y. Separation operations are performed from the second or bottom side 122 in the implementations described below and the first side 121 of the wafer 101 is supported on carrier structures, such as adhesive carrier tape allowing the wafer 101 to be transported and supported in various tools of the system 100.

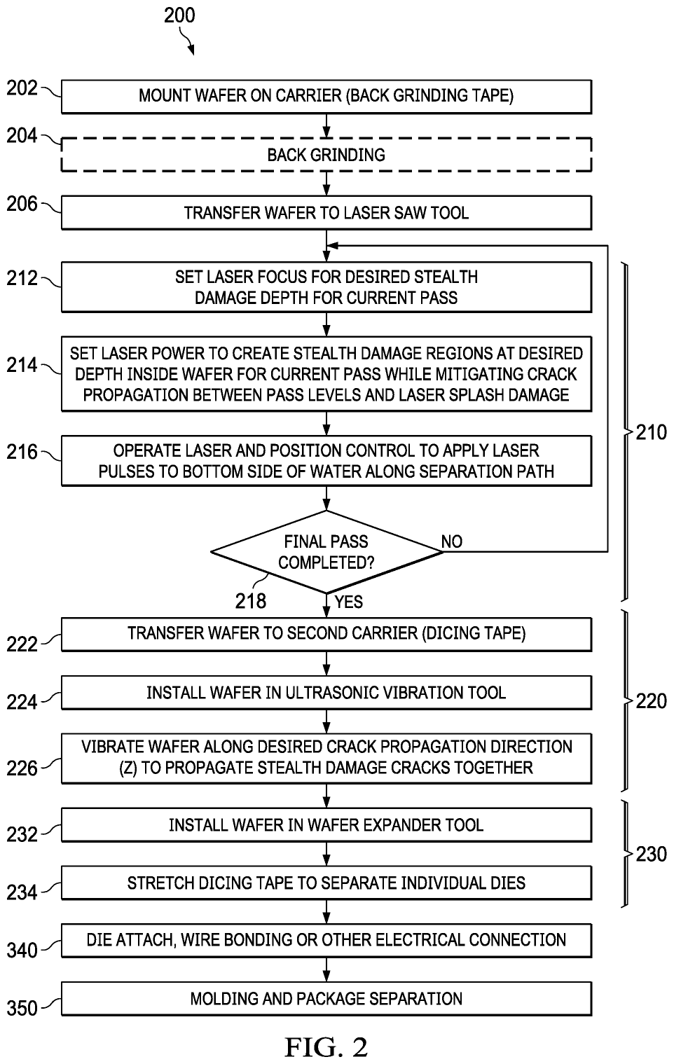

The tools 104, 106 and 108 are configured by suitable arrangement and programming in one example to separate the individual semiconductor dies 110 from the starting wafer 101, examples of which are described further below in connection with FIGS. 2-7. In operation, the laser saw tool 104 applies laser pulses to the second side 122 of the wafer 101 to create stealth damage regions at respective depths along the third direction Z. The laser pulses also create cracks that extend above and below the respective stealth damage regions. In the illustrated example, the laser saw tool 104 is configured with laser power settings such that the cracks formed by the laser pulses extend upward and downward in the wafer 101 from along the third direction Z but the cracks associated with different stealth damage regions at different depths along the third direction Z are not joined together and instead are spaced apart from one another along a third direction Z.

In one example, the laser saw tool 104 is configured to operate a laser and a position controller to apply laser pulses to the second side 122 of the wafer 101 along a separation path at laser power and focus settings to create the stealth damage regions at target depths in the wafer 101 and to create the cracks that extend in the wafer 101 from the stealth damage regions without propagating to other cracks in the wafer 101. The configuration of the laser saw tool 104 with controlled laser energy application mitigates splash damage in the wafer 101 during laser cutting. As noted, the laser stealth damage operation of the laser saw tool 104 creates localized stealth damage regions at two or more depths along the third direction Z in a desired separation pattern, for example, through scanning along the scribe regions 111 shown in FIG. 1, where the laser power creates cracks above and below the respective stealth damage regions without the cracks of stealth damage regions at one depth propagating far enough to connect to cracks of another stealth damage region at a different depth.

The vibration tool 106 is configured to apply 220 a compressive and retractive cyclical force to the wafer 101 along the third direction Z to propagate and join the cracks from the respective stealth damage regions together. In the illustrated implementations below, stealth damage regions are created at two depths using the laser saw tool 104, and the wafer 101 is vibrated (e.g., mechanically actuated) back and forth along the third direction Z such that the lower cracks from the deeper stealth damage regions propagate downward to the first side 121 of the wafer 101, and the upper cracks from the deeper stealth damage regions propagate upward. The compressive and retractive cyclical force along the third direction Z concurrently extends or propagates the cracks of the upper stealth damage regions such that the lower cracks from the shallower stealth damage regions propagate downward along the third direction Z to join with the upper cracks from the deeper stealth damage regions, and the upper cracks from the shallower stealth damage regions propagate upward to the second side 122 of the wafer 101. The configuration of the vibration tool 106 facilitates die separation throughout the third direction extent of the wafer 101 in the scribe regions 111 while mitigating die un-separation and chipping or meander faults associated with higher power laser cutting. In one example, the vibration tool 106 is configured to apply ultrasonic cyclical force to the wafer 101 in a fluid bath. In another example, the vibration tool 106 is configured to apply ultrasonic cyclical force to a wafer chuck table that supports the wafer 101. In a further example, the vibration tool 106 is configured to support the wafer 101 on a tape carrier in a flexible frame, support the flexible frame with a ring type wafer table, in which the wafer 101 has no physical contact with the wafer table, and apply ultrasonic cyclical force to the wafer table.

The wafer expander tool 108 is configured to expand the wafer 101 along the first and second directions X and Y in order to separate the individual dies 110 from the wafer 101. In one example, the wafer expander tool 108 is configured to support the wafer 101 on a carrier tape and stretch 234 the carrier tape 601 along the first and second directions X and Y to separate individual dies 110 from the wafer 101. In combination, the configuration of the laser saw tool 104 to mitigate initial crack propagation while also mitigating laser splash damage, and the configuration of the vibration tool 106 to finish crack propagation to provide a solution that addresses all these problems causing reduced product yield.

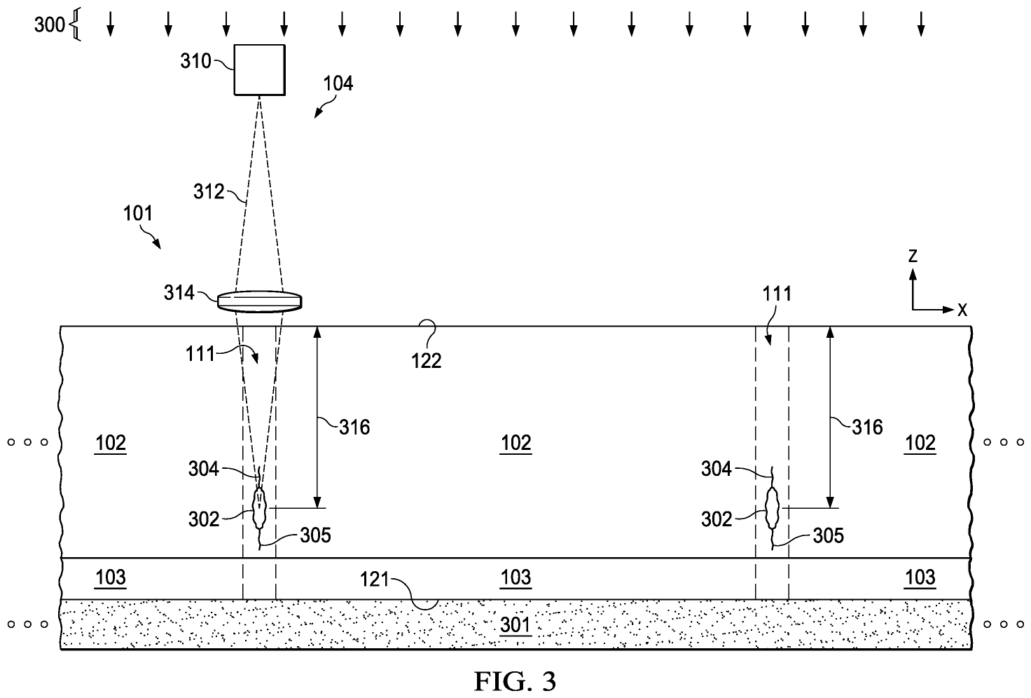

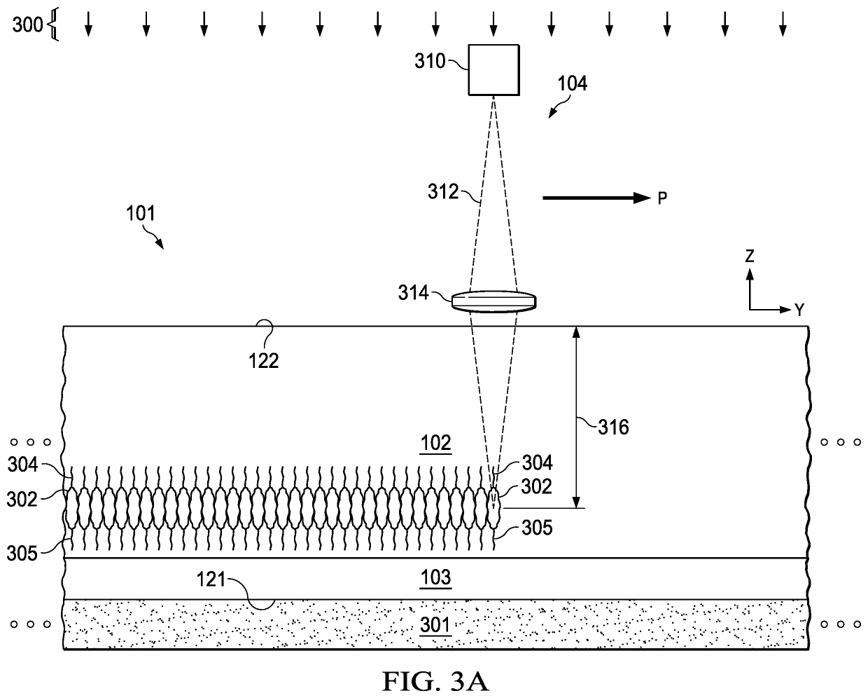

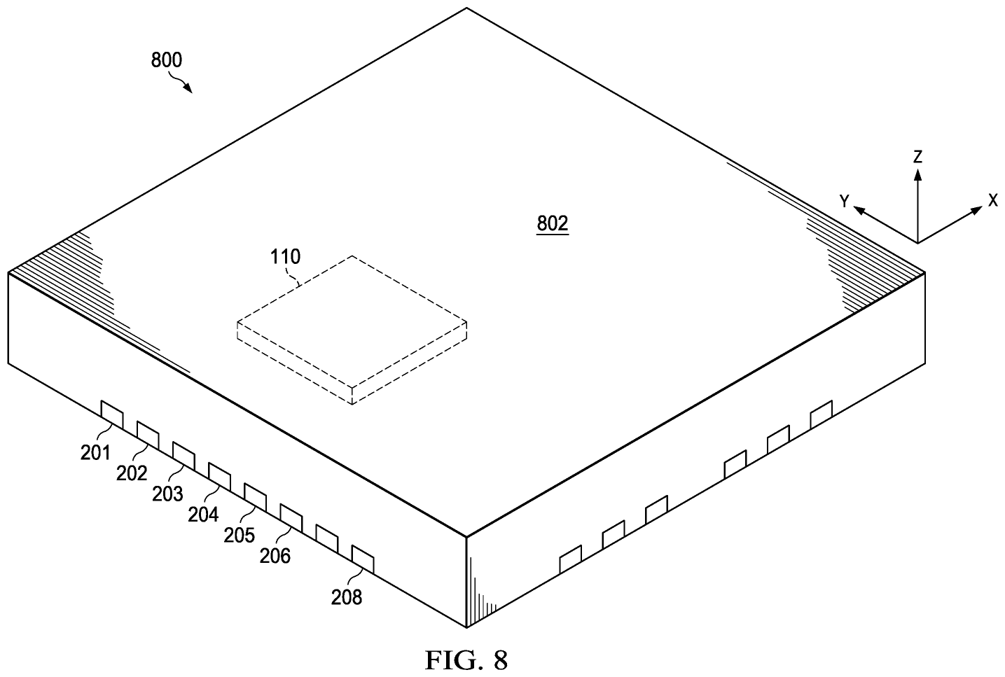

Referring also to FIGS. 2-8, FIG. 2 shows a method 200 for fabricating an electronic device with an included method for separating dies 110 from a wafer 101, FIGS. 3-7 show the die separation of the dies 110 of the wafer 101 in the system 100, and FIG. 8 shows a finished packaged electronic device produced by the method 200. The method 200 is shown after wafer processing of the first (top) side of the wafer 101 to build transistors, capacitors, resistors, diodes, etc. on or in the semiconductor layer 102 and to form one or more metallization layers in the active circuit portion 103 prior to die separation. At 202 in FIG. 2, the wafer is mounted on a carrier structure. FIG. 3 shows one example, in which the wafer 101 is mounted with the first side 121 on an adhesive carrier tape 301 at 202. In one example, the wafer 101 undergoes optional back grinding at 204, for example, to planarize the second side 122 and to set a final desired die thickness.

Referring also to FIGS. 3 and 3A, the wafer 101 is transferred to the laser saw tool 104 (at 202 in FIG. 2) for laser cutting using stealth damage techniques. FIG. 3 shows one example, in which the laser saw tool 104 implements a laser cutting process 300. The laser saw tool 104 includes a laser 310 operative to generate and direct a laser beam 312 through a focus lens 314 along the third direction Z toward the second side 122 of the wafer 101. FIGS. 3 and 3A show a portion of the wafer 101 undergoing a first pass stealth cutting process 300 in the laser saw tool 104 to create first stealth damage regions 302 and associated upper and lower cracks 304 and 305 at a first depth 316 along a separation path P at 210 of FIG. 2.

The method 200 includes applying laser pulses at 210 to the second side 122 of the wafer 101. One implementation includes applying laser pulses of respective focal distances along the third direction Z as the laser 310 is translated through a programmed scan path along the scribe regions 111 of FIG. 1 between the prospective die areas of the wafer 101. The processing at 210 in one example is a two-pass operation that creates first and second stealth damage regions at respective first and second depths in the wafer 101. In another example, more than two sets of stealth damage regions are created at respective depth distances below the second side 122 of the wafer 101. In one implementation, for each pass at 212, a laser focus or focal distance adjustment is set to focus the laser beam 312 at a target depth. In the example first pass in FIGS. 3 and 3A, the focus adjustment is set for a desired or target first depth 316. The method 200 in one example also includes setting a laser power at 214 to create the stealth damage regions at the target depth 316 in the wafer 101. The method 200 in this example also includes operating the laser 310 and a position controller (not shown) at 216 to apply laser pulses to the second side 122 of the wafer 101 along a scan path or separation path P. In the illustrated example, the separation path P follows the

FIGS. 3 and 3A show portions of a first pass laser cutting process 300 that generates laser pulses as the laser 310 is translated relative to the wafer 101 along the separation path P to create first stealth damage regions 302 at the first depth 316. The separation path P in this example is aligned in the X and Y directions along the scribe regions 111 of FIG. 1 between the prospective die areas of the wafer 101. As shown in FIG. 3A, the pulse frequency and scan rate are set in one example such that the successive first stealth damage regions 302 overlap or are adjacent and form a continuous laser damage line parallel to the separation path P, centered along the third direction Z at the first depth 316. The laser pulses also create respective first and second (e.g., upper and lower) cracks 304 and 305 that extend from the first stealth damage regions 302 upward and downward from the stealth damage regions 302 in the wafer 101 along the third direction Z.

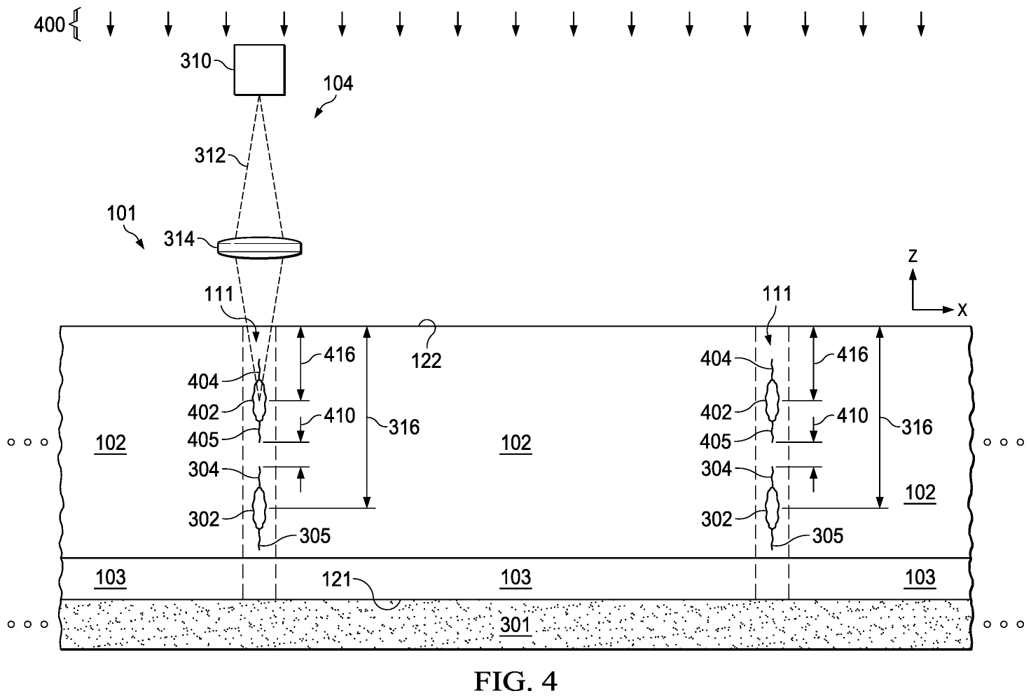

At 218 in FIG. 2, the laser saw tool 104 determines whether the final pass of the multi-pass processing at 210 has been completed. If not (NO at 218), the method 200 returns to 212 for the next pass. In the illustrated two-pass example, the second pass includes setting the laser focus or focal distance adjustment at 212 to focus the laser beam 312 at a shallower second target depth 416 in FIG. 4, and the laser power is set at 214. In one example, the power settings are the same for both passes. In another example, the power settings are different for the first and second passes. At 216, the laser 310 and position controller are operated to apply laser pulses to the second side 122 of the wafer 101 along the separation path P. FIG. 4 shows one example, in which the wafer 101 undergoes the second pass of the multi-pass laser stealth cutting operation 210 to create second stealth damage regions 402 and associated cracks 404 and 405 at a shallower second depth 416 along the scribe regions 111 of FIG. 1 using the same separation path P. The laser power is set at 214 and the to create the stealth damage regions 402 at the second target depth 416 in the wafer 101.

As seen in FIG. 4, the controlled laser energy application in the two passes creates cracks above and below the respective stealth damage regions without the cracks of stealth damage regions at one depth not propagating far enough to connect to cracks of another stealth damage region at a different depth. The applied laser pulses at 210 in multiple pulses create the localized stealth damage regions 302 and 402 at different depths 316, 416 along the third direction Z in a desired separation pattern along the scribe regions 111, where the laser power controls the propagation of the cracks 304, 305, 404, and 406 above and below the respective stealth damage regions 302 and 402 the cracks of stealth damage regions at one depth not propagating far enough to connect to cracks of another stealth damage region at a different depth. In the illustrated example, the cracks 304 and 405 are spaced apart from one another by a non-zero distance 410 along the third direction Z, and the cracks 305 and 404 do not extend to (e.g., are spaced apart from) the respective first and second sides 121 and 122 of the wafer 101 along the third direction Z. While this does not provide sufficient crack propagation for final device separation without meander faults or die un-separation, this laser power control configuration mitigates laser splash damage during the stealth damage laser pulse processing at 210.

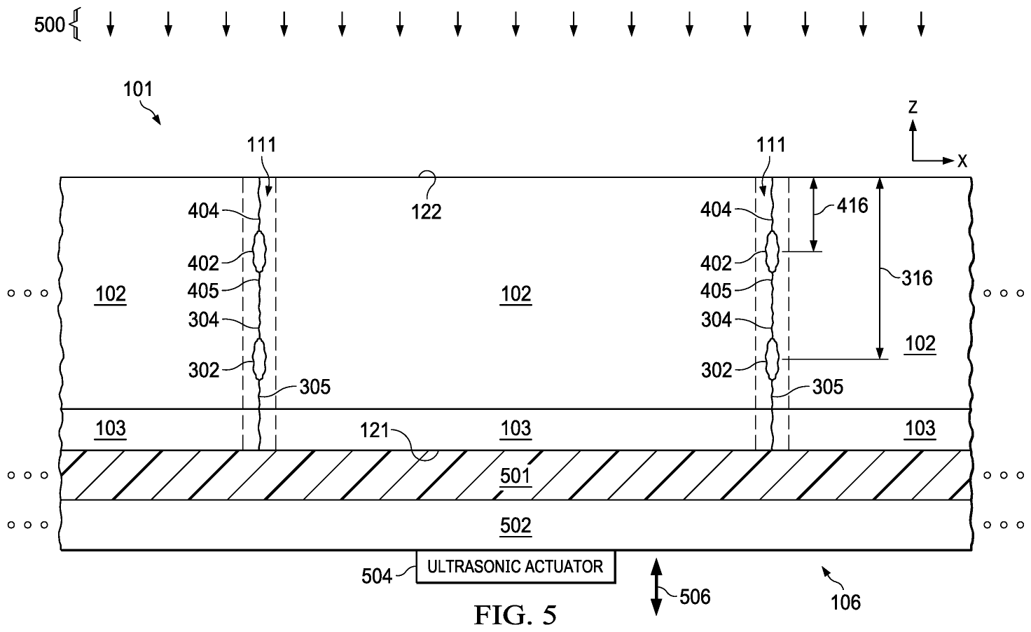

Once the final laser pass has been completed (YES at 218 in FIG. 2), the method 200 continues with compressive and retractive cyclical force application to the wafer 101 at 220. The processing at 220 addresses the crack spacing, and further propagates the cracks 304, 305, 404, and 406 such that the cracks 304 and 405 join together and the cracks 305 and 404 propagate further to the respective first and second sides 121 and 122 of the wafer 101 along the third direction Z. FIG. 5 shows one example, in which the wafer 101 is transferred at 222 to a second carrier, for example, an adhesive dicing tape carrier 501 and is transferred to the ultrasonic vibration tool 106 at 224 and supported on a wafer chuck or other fixture 502.

At 226 in FIG. 2, the wafer 101 is vibrated along the desired crack propagation direction (e.g., the third direction Z) to propagate the cracks 304, 305, 404, and 405 from the respective stealth damage regions 302 and 402 and join the cracks 304 and 405 together. The wafer chuck 502 in the example of FIG. 5 is operationally coupled to an ultrasonic actuator 504. The actuator 504 is configured to apply cyclical mechanical force in an oscillation direction 506 to the chuck 502 and the wafer 101 along the third direction Z. In one example, the actuator 504 applies substantially sinusoidal cyclical mechanical force to the wafer 101, directly or indirectly, along the third direction Z. In another implementation, actuator 504 is configured to apply the cyclical mechanical force of a different waveform or wave shape (e.g., non-sinusoidal). The applied cyclical mechanical force also propagates the cracks 305 and 404 to the respective first and second sides 121 and 122 of the wafer 101 as shown in FIG. 5.

In one example, the ultrasonic vibration tool 106 includes a fluid bath, such as deionized water, and the actuator 504 is coupled with the fluid. The wafer 101 is supported on a carrier submerged in the fluid, and the actuator 504 applies compressive and retractive cyclical force to the fluid to vibrate the wafer 101 in the fluid bath. In one implementation, the actuator 504 applies the ultrasonic cyclical force at a frequency less than 90 kHz, for example approximately 15 kHz for approximately 60 seconds. In another example, the ultrasonic vibration tool 106 includes a wafer chuck table that supports the wafer 101 and the carrier tape 501, and the actuator 504 is mechanically coupled to provide compressive and retractive cyclical force to the wafer chuck table. In one implementation, the actuator 504 applies the ultrasonic cyclical force to the wafer chuck table at a frequency less than 90 kHz, for example approximately 15 kHz for approximately 60 seconds or less. In another example, the ultrasonic vibration tool 106 includes a flexible frame with a ring type wafer table that supports the wafer 101 on the tape carrier 501, in which the wafer 101 has no physical contact with the wafer table. In this example, the wafer 101 is supported on the tape carrier in the flexible frame, the flexible frame is supported relative to the ring type wafer table, and the actuator 504 is mechanically coupled to provide compressive and retractive cyclical force to the wafer table. The actuator 504 provides compressive and retractive cyclical force to the wafer table and indirectly to the wafer 101. Other implementations can be used by which compressive and retractive cyclical force is applied, directly or indirectly, to the wafer 101 at 220.

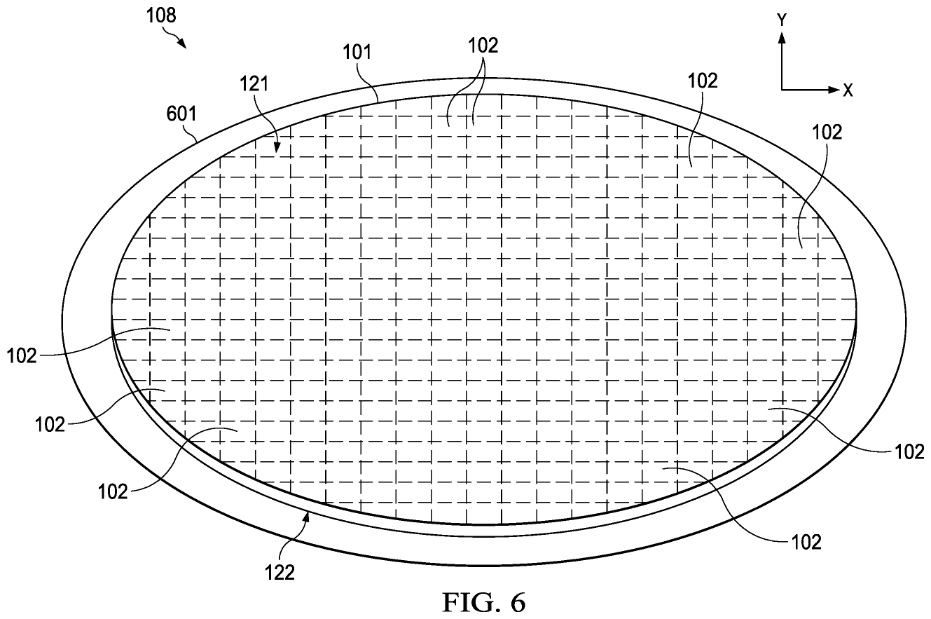

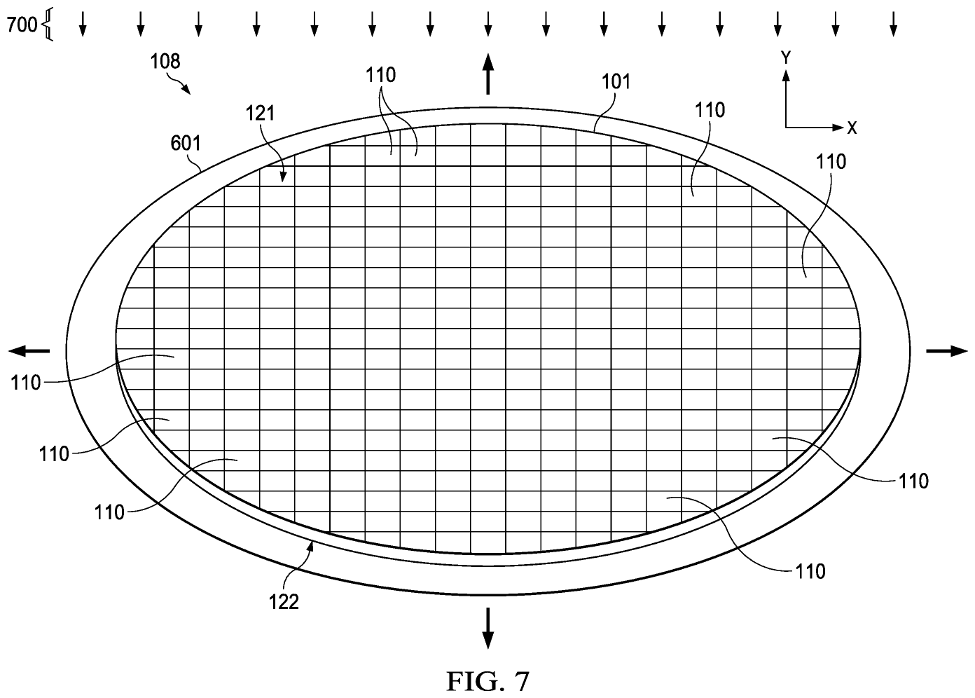

The method 200 in FIG. 2 continues at 230 with expanding the wafer 101 along the first and second directions X and Y to separate individual dies 110 from the wafer 101. One implementation includes installing the wafer 101 on a dicing tape carrier in the wafer expander tool 108 at 232 and stretching the dicing tape at 234 to separate the individual dies 110. FIG. 6 shows one example, in which the wafer is supported at 232 on a carrier tape 601 with the second side 122 of the wafer 101 adhered to the carrier tape 601. In FIG. 7, a stretching process 700 is performed that stretches the carrier tape 601 outward along the first and second directions X and Y as shown by the arrows in FIG. 7 to separate the individual dies 110 from the wafer 101. The die singulation processing is then complete, and the dies 110 can be transferred to a packaging operation for assembly into packaged electronic devices, for example, integrated circuits.

At 340 in FIG. 2, the electronic device fabrication example continues with die attach processing to attach one of the individual dies 110 to a die attach pad or package substrate. One or more electrical connection processes are also performed at 340, for example, flip-chip die attach soldering and/or wire bonding to electrically connect one or more terminals of the individual die 110 to a circuit or conductive lead of the prospective device. At 350, molding and package separation operations are performed to provide a finished packaged electronic device. FIG. 8 shows one example packaged electronic device 800 that includes a separated semiconductor die 110 in a molded package structure 802 that exposes bottoms or sides of conductive device leads or terminals 201-208 which can be soldered to a host printed circuit board (PCB, no shown).

The use of lower laser power in various implementations mitigates or avoids laser splash damage in the wafer 101 during laser cutting, and application of compressive and retractive cyclical force using the vibration tool 106 facilitates die separation throughout the third direction extent of the wafer 101 while mitigating die un-separation and chipping or meander faults associated with higher power laser cutting. In one example, the laser pulse power is set to a non-zero value that is 0.5 W or less (e.g., at 214 in FIG. 2) to mitigate or avoid laser splash damage. In contrast, using a higher laser power (e.g., greater than 1 W, such as approximately 2 W) can increase the likelihood and extent of laser splash damage. In certain implementations, the vibration tool 106 applies a balanced compressive and retractive cyclical force uniformly across the wafer 101 (e.g., at 226) and causes the laser induced cracks to propagate further and allow internal cracks (e.g., cracks 304 and 405) to connect to each other, and the top and bottom layer cracks (e.g., cracks 305 and 404) to reach the device active circuit side and backside and surfaces 122 and 121, respectively. The balanced cyclical vibration frequency, amplitude and/or power settings can be tailored in a given application to help control the crack propagation to follow the separation path/direction of the originally created laser induced cracks. In one example, for a silicon wafer 101 having a diameter of 300 mm and Z-direction thickness of 130 um and a 0.8 mm×1.3 mm target die size, the laser saw tool 104 is or includes an NS900 laser tool for laser saw processing at 210 at a laser power setting of 0.5 W or less. In this example, the cyclical vibration is applied with the wafer 101 mounted on a Flexframe flexible frame using a D821HS dicing tape. In another implementation, the vibration tool 106 is or includes a MU-1200 Batch type ultrasonic tool, with a de-ionized (DI) water media to apply cyclic compressive and retractive force to the wafer 101 using ultrasonic force via the DI water bath for approximately 60 seconds at 15 khz. The use of low power laser stealth damage region creation in some examples shows a heavy black line along the separation path P in the scribe regions 111 indicating that the cracks did not connect during laser saw processing. Described examples facilitate very low power laser saw parameters that provide significant process margin against laser splash damage failure modes. In addition to the advantage of low to zero risk of laser splash damage, the described examples facilitate high quality (e.g., high yield) for the laser saw process, including benefits such as good die separation rate, good meandering and chipping performance.

Modifications are possible in the described examples, and other implementations are possible, within the scope of the claims.

What is claimed is:

1. A method of separating dies from a wafer, the method comprising:
applying laser pulses to a side in a plane of orthogonal first and second directions of the wafer to create first and second stealth damage regions at respective first and second depths in the wafer and to create cracks that extend in the wafer from the respective stealth damage regions and that are spaced apart from one another along a third direction that is orthogonal to the first and second directions;
applying a compressive and retractive cyclical force to the wafer along the third direction to propagate and join the cracks from the respective stealth damage regions together; and
expanding the wafer along the first and second directions to separate individual dies from the wafer.

2. The method of claim 1, wherein applying the compressive and retractive cyclical force to the wafer comprises applying ultrasonic cyclical force to the wafer in a fluid bath.

3. The method of claim 2, wherein the ultrasonic cyclical force is applied at a frequency of 90 kHz or less.

4. The method of claim 1, wherein applying the compressive and retractive cyclical force to the wafer comprises applying ultrasonic cyclical force to a wafer chuck table that supports the wafer.

5. The method of claim 1, wherein applying the compressive and retractive cyclical force to the wafer comprises:
supporting the wafer on a tape carrier in a flexible frame;
supporting the flexible frame with a ring type wafer table, in which the wafer has no physical contact with the wafer table; and
applying ultrasonic cyclical force to the wafer table.

6. The method of claim 1, wherein applying the laser pulses comprises, for each of first and second passes:
setting a laser focus to focus a laser beam at a target depth;
setting a laser power to create the stealth damage regions at the target depth in the wafer and to create the cracks that extend in the wafer from the stealth damage regions without propagating to other cracks in the wafer; and
operating a laser and a position controller to apply laser pulses to the side of the wafer along a separation path.

7. The method of claim 1, wherein expanding the wafer comprises:
supporting the wafer on a carrier tape; and
stretching the carrier tape along the first and second directions to separate individual dies from the wafer.

8. A method of fabricating an electronic device, the method comprising:
applying laser pulses to a side in a plane of orthogonal first and second directions of a wafer to create first and second stealth damage regions at respective first and second depths in the wafer and to create cracks that extend in the wafer from the respective stealth damage regions and that are spaced apart from one another along a third direction that is orthogonal to the first and second directions;
applying a compressive and retractive cyclical force to the wafer along the third direction to propagate and join the cracks from the respective stealth damage regions together;
expanding the wafer along the first and second directions to separate individual dies from the wafer;
attaching one of the individual dies to a die attach pad or package substrate;
electrically connecting a terminal of the one of the individual dies to a circuit or conductive lead; and
enclosing the one of the individual dies in a package structure.

9. The method of claim 8, wherein applying the compressive and retractive cyclical force to the wafer comprises applying ultrasonic cyclical force to the wafer in a fluid bath.

10. The method of claim 9, wherein the ultrasonic cyclical force is applied at a frequency of 90 kHz or less.

11. The method of claim 8, wherein applying the compressive and retractive cyclical force to the wafer comprises applying ultrasonic cyclical force to a wafer chuck table that supports the wafer.

12. The method of claim 8, wherein applying the compressive and retractive cyclical force to the wafer comprises:
supporting the wafer on a tape carrier in a flexible frame;
supporting the flexible frame with a ring type wafer table, in which the wafer has no physical contact with the wafer table; and
applying ultrasonic cyclical force to the wafer table.

13. The method of claim 8, wherein applying the laser pulses comprises, for each of first and second passes:
setting a laser focus to focus a laser beam at a target depth;
setting a laser power to create the stealth damage regions at the target depth in the wafer and to create the cracks that extend in the wafer from the stealth damage regions without propagating to other cracks in the wafer; and
operating a laser and a position controller to apply laser pulses to the side of the wafer along a separation path.

14. The method of claim 8, wherein expanding the wafer comprises:
supporting the wafer on a carrier tape; and
stretching the carrier tape along the first and second directions to separate individual dies from the wafer.

15. A system, comprising:
a laser saw tool configured to apply laser pulses to a side in a plane of orthogonal first and second directions of a wafer to create first and second stealth damage regions at respective first and second depths in the wafer and to create cracks that extend in the wafer from the respective stealth damage regions and that are spaced apart from one another along a third direction that is orthogonal to the first and second directions;
a vibration tool configured to apply a compressive and retractive cyclical force to the wafer along the third direction to propagate and join the cracks from the respective stealth damage regions together; and
a wafer expander tool configured to expand the wafer along the first and second directions to separate individual dies from the wafer.

16. The system of claim 15, wherein the vibration tool is configured to apply ultrasonic cyclical force to the wafer in a fluid bath.

17. The system of claim 15, wherein the vibration tool is configured to apply ultrasonic cyclical force to a wafer chuck table that supports the wafer.

18. The system of claim 15, wherein the vibration tool is configured to:
support the wafer on a tape carrier in a flexible frame;
support the flexible frame with a ring type wafer table, in which the wafer has no physical contact with the wafer table; and
apply ultrasonic cyclical force to the wafer table.

19. The system of claim 15, wherein the laser saw tool is configured to operate a laser and a position controller to apply laser pulses to the side of the wafer along a separation path at laser power and focus settings to create the stealth damage regions at the target depth in the wafer and to create the cracks that extend in the wafer from the stealth damage regions without propagating to other cracks in the wafer.

20. The system of claim 15, wherein the wafer expander tool configured to support the wafer on a carrier tape and stretch the carrier tape along the first and second directions to separate individual dies from the wafer.
